(19) United States
(12) Patent Application Publication
(10) Pub. No.: US 2025/0309856 A1
(43) Pub. Date: Oct. 2, 2025

(54) MULTILAYERED ELECTRONIC COMPONENT

(71) Applicant: TDK Corporation, Tokyo (JP)

(72) Inventor: Jun NAKATSUTSUMI, Tokyo (JP)

(73) Assignee: TDK Corporation, Tokyo (JP)

(21) Appl. No.: 19/090,442

(22) Filed: Mar. 26, 2025

(30) Foreign Application Priority Data
Mar. 28, 2024 (JP) 2024-054334

(51) Int. Cl. H03H 7/01

(52) U.S. Cl. CPC H03H 7/1741; H03H 7/0161

(57) ABSTRACT

An electronic component includes a stack, a shield conductor integrated into the stack, at least one first columnar conductor, at least one second columnar conductor, an inductor including an inductor conductor layer connecting the at least one first columnar conductor and the at least one second columnar conductor, and at least one third columnar conductor connected to the ground. The shield conductor includes a first conductor part provided to a first side surface of the stack and a second conductor part provided to a second side surface of the stack. The at least one third columnar conductor is arranged between the inductor and the first conductor part.

### CROSS-REFERENCE TO RELATED APPLICATION

This application claims the benefit of Japanese Priority Patent Application No. 2024-054334, filed on Mar. 28, 2024, the entire contents of which are incorporated herein by reference.

### BACKGROUND

The disclosure relates to a multilayered electronic component including a shield conductor integrated into a stack.

Compact mobile communication apparatuses widely use a configuration in which an antenna is provided to be commonly used by a system and a plurality of applications different in frequency band in use and a plurality of signals transmitted/received by this antenna are separated by using a branching filter.

A typical branching filter for separating a first signal of a frequency within a first frequency band and a second signal of a frequency within a second frequency band higher than the first frequency band includes a common port, a first signal port, a second signal port, a first filter provided in a first signal path from the common port to the first signal port, and a second filter provided to a second signal path from the common port to the second signal port. As first and second filters, LC resonators each composed by using an inductor and a capacitor are used, for example.

The recent market demands for reduction in size and footprint of compact mobile communication apparatuses and have also required miniaturization of branching filters for use in those communication apparatuses. As branching filters suitable for miniaturization, multilayered branching filters using a stack including a plurality of dielectric layers stacked together and a plurality of conductor layers are known. As an inductor used for such a multilayered branching filter, an inductor composed of a conductor layer and a columnar conductor extending in a stacking direction of a plurality of dielectric layers is known. Such an inductor is disclosed in JP 2021-121110 A, for example.

With such reduction in size and footprint of compact mobile communication apparatuses, densification in mounting of electronic components to be used for communication apparatuses has been proceeding. Consequently, space between a plurality of electronic components mounted on a mounting board is reduced. With the space between a plurality of electronic components being reduced, electromagnetic interference between the plurality of electronic components is more likely to occur. To suppress such electromagnetic interference, provision of a shield to a main body of an electronic component is conceivable. JP 2017-076796 A discloses an electronic component being a multilayered electronic component with an external electrode(s) being provided to a bottom surface of a stack of the multilayered electronic component and a shield electrode being provided to surfaces of the stack of the multilayered electronic component other than the bottom surface.

When an inductor composed of a conductor layer and a columnar conductor as that disclosed in JP 2021-121110 A is applied to an electronic component including a shield as that disclosed in JP 2017-076796 A, reduction in size of a stack may cause coupling between the columnar conductors and the shield to be too strong to provide desired characteristics consequently.

The above problem is applicable, without being limited to multilayered branching filters, to multilayered electronic components in general including a shield, and an inductor composed of a conductor layer and a columnar conductor.

### SUMMARY

A multilayered electronic component according to a first aspect of one embodiment of the disclosure includes: a stack including a plurality of dielectric layers stacked together; a shield conductor integrated into the stack; at least one first columnar conductor and at least one second columnar conductor each extending in a stacking direction of the plurality of dielectric layers; an inductor including an inductor conductor layer connecting the at least one first columnar conductor and the at least one second columnar conductor; and at least one third columnar conductor extending in the stacking direction and connected to the ground. The stack has a first surface and a second surface located at both respective ends in the stacking direction and a first side surface, a second side surface, a third side surface, and a fourth side surface connecting the first surface and the second surface. The first side surface and the second side surface are opposite to each other. The third side surface and the fourth side surface are opposite to each other.

The shield conductor includes a first conductor part provided to the first side surface and a second conductor part provided to the second side surface. The inductor conductor layer has a first end and a second end extending from the first side surface toward the second side surface and located at both respective longitudinal-direction ends of the inductor conductor layer. The at least one first columnar conductor is connected to a portion of the inductor conductor layer near the first end. The at least one second columnar conductor is connected to a portion of the inductor conductor layer near the second end. The at least one third columnar conductor is arranged between the inductor and the first conductor part.

A multilayered electronic component according to a second aspect of one embodiment of the disclosure includes: a stack including a plurality of dielectric layers stacked together; a shield conductor integrated into the stack; at least one first columnar conductor and at least one second columnar conductor each extending in a stacking direction of the plurality of dielectric layers; an inductor including an inductor conductor layer connecting the at least one first columnar conductor and the at least one second columnar conductor; and a ground conductor layer connected to the ground. The stack includes a first surface and a second surface located at both respective ends in the stacking direction. The shield conductor includes a conductor part provided to the first surface. The ground conductor layer is arranged between the inductor and the conductor part.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a circuit diagram showing an example of a circuit configuration of a multilayered electronic component according to an example embodiment of the disclosure.

FIG. 2 is a perspective view showing an external appearance of the multilayered electronic component according to the example embodiment of the disclosure.

FIG. 3 is a perspective view showing a stack of the multilayered electronic component according to the example embodiment of the disclosure.

FIG. 4A to FIG. 4C are explanatory diagrams showing respective patterned surfaces of first to third dielectric layers of the stack of the multilayered electronic component according to the example embodiment of the disclosure.

FIG. 5A to FIG. 5C are explanatory diagrams showing respective patterned surfaces of fourth to sixth dielectric layers of the stack of the multilayered electronic component according to the example embodiment of the disclosure.

FIG. 6A and FIG. 6B are explanatory diagrams showing respective patterned surfaces of seventh and eighth dielectric layers of the stack of the multilayered electronic component according to the example embodiment of the disclosure.

FIG. 6C is an explanatory diagram showing a patterned surface of ninth to eleventh dielectric layers of the stack of the multilayered electronic component according to the example embodiment of the disclosure.

FIG. 7A to FIG. 7C are explanatory diagrams showing respective patterned surfaces of twelfth to fourteenth dielectric layers of the stack of the multilayered electronic component according to the example embodiment of the disclosure.

FIG. 8A to FIG. 8C are explanatory diagrams showing respective patterned surfaces of fifteenth to seventeenth dielectric layers of the stack of the multilayered electronic component according to the example embodiment of the disclosure.

FIG. 9A to FIG. 9C are explanatory diagrams showing respective patterned surfaces of eighteenth to twentieth dielectric layers of the stack of the multilayered electronic component according to the example embodiment of the disclosure.

FIG. 10A to FIG. 10C are explanatory diagrams showing respective patterned surfaces of twenty-first to twenty-third dielectric layers of the stack of the multilayered electronic component according to the example embodiment of the disclosure.

FIG. 11 is an explanatory diagram showing a patterned surface of a twenty-fourth dielectric layer of the stack of the multilayered electronic component according to the example embodiment of the disclosure.

FIG. 12 is a perspective view showing an internal structure of the stack of the multilayered electronic component according to the example embodiment of the disclosure.

FIG. 13 is a perspective view showing part of the internal structure of the stack of the multilayered electronic component according to the example embodiment of the disclosure.

FIG. 14 is a plan view showing part of the internal structure of the multilayered electronic component according to the example embodiment of the disclosure.

FIG. 15 is a perspective view showing part of the internal structure of the stack of the multilayered electronic component according to the example embodiment of the disclosure.

FIG. 16 is a characteristic chart showing frequency characteristics of isolation of each of a model of an example and a model of a comparative example obtained by a simulation.

### DETAILED DESCRIPTION

An object of the disclosure is to provide a multilayered electronic component including a shield conductor integrated into a stack and an inductor composed of a conductor layer and a columnar conductor, to be capable of providing desired characteristics while suppressing occurrence of a problem attributable to the shield conductor.

In the following, some example embodiments and modification examples of the disclosure will be described in detail with reference to the accompanying drawings. Note that the following description is directed to illustrative examples of the disclosure and not to be construed as limiting the disclosure. Factors including, without limitation, numerical values, shapes, materials, components, positions of the components, and how the components are coupled to each other are illustrative only and not to be construed as limiting the disclosure. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. The description will be given in the following order.

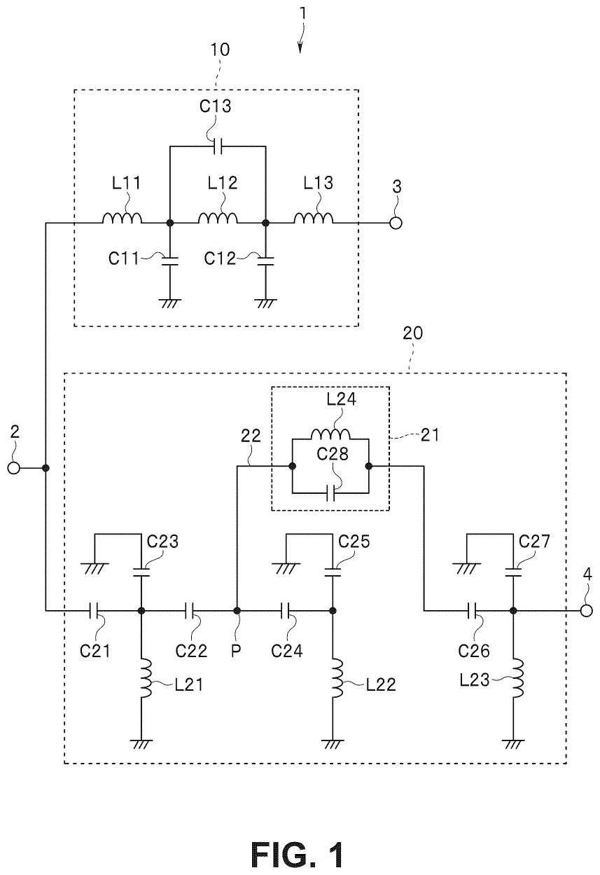

First, reference is made to FIG. 1 to describe a schematic configuration of a multilayered electronic component (hereinafter referred to simply as an electronic component) 1 according to an example embodiment of the disclosure. FIG. 1 is a circuit diagram showing a circuit configuration of the electronic component 1. FIG. 1 shows a branching filter (diplexer) as an example of the electronic component 1. The electronic component 1 includes a common terminal 2, a first signal terminal 3, a second signal terminal 4, a first filter 10, and a second filter 20.

The first filter 10 is provided between the common terminal 2 and the first signal terminal 3 in a circuit configuration. The second filter 20 is provided between the common terminal 2 and the second signal terminal 4 in the circuit configuration. Note that, in the present application, the expression “in a/the circuit configuration” is used to indicate not a layout in a physical configuration but a layout in a circuit diagram.

The first filter 10 is a filter that selectively allows a signal of a frequency in a first passband to pass. The second filter 20 is a filter that selectively allows a signal of a frequency in a second passband to pass, the second passband being higher than the first passband. The first and second filters 10 and 20 are each configured by an LC filter circuit including at least one inductor and at least one capacitor. The first filter 10 corresponds to a “first circuit” in the disclosure. The second filter 20 corresponds to a “second circuit” in the disclosure.

A first signal of the frequency in the first passband input to the common terminal 2 selectively passes the first filter 10 and is then output from the first signal terminal 3. A second signal of the frequency in the second passband input to the common terminal 2 selectively passes the second filter 20 and is then output from the second signal terminal 4. The electronic component 1 separates the first and second signals in this way.

Reference is now made to FIG. 1 to describe examples of configurations of the first and second filters 10 and 20. First, the configuration of the first filter 10 will be described. The first filter 10 includes inductors L11, L12, and L13 and capacitors C11, C12, and C13.

One end of the inductor L11 is connected to the common terminal 2. One end of the inductor L12 is connected to the other end of the inductor L11. One end of the inductor L13 is connected to the other end of the inductor L12. The other end of the inductor L13 is connected to the first signal terminal 3.

One end of the capacitor C11 is connected to a connection point of the inductor L11 and the inductor L12. One end of the capacitor C12 is connected to a connection point of the inductor L12 and the inductor L13. The other end of each of the capacitors C11 and C12 is connected to the ground. The capacitor C13 is connected to the inductor L12 in parallel.

Next, the configuration of the second filter 20 will be described. The second filter 20 includes a first inductor L21, a second inductor L22, a third inductor L23, a fourth inductor L24, and capacitors C21, C22, C23, C24, C25, C26, C27, and C28.

One end of the capacitor C21 is connected to the common terminal 2. One end of the capacitor C22 is connected to the other end of the capacitor C21.

One end of the first inductor L21 is connected to a connection point of the capacitor C21 and the capacitor C22. The other end of the first inductor L21 is connected to the ground. One end of the capacitor C23 is connected to one end of the first inductor L21. The other end of the capacitor C23 is connected to the ground.

One end of the capacitor C24 is connected to the other end of the capacitor C22. One end of the second inductor L22 is connected to the other end of the capacitor C24. The other end of the second inductor L22 is connected to the ground. One end of the capacitor C25 is connected to one end of the second inductor L22. The other end of the capacitor C25 is connected to the ground.

One end of the fourth inductor L24 is connected to a connection point of the capacitor C22 and the capacitor C24. The capacitor C28 is connected to the fourth inductor L24 in parallel.

One end of the capacitor C26 is connected to the other end of the fourth inductor L24. The other end of the capacitor C26 is connected to the second signal terminal 4. One end of the third inductor L23 is connected to the other end of the capacitor C26. The other end of the third inductor L23 is connected to the ground. One end of the capacitor C27 is connected to one end of the third inductor L23. The other end of the capacitor C27 is connected to the ground.

The second filter 20 further includes a parallel resonant circuit 21. In FIG. 1, a reference sign P indicates a node between the one end of the first inductor L21 and the one end of the second inductor L22 in the circuit configuration. The parallel resonant circuit 21 is provided to a path 22 connecting the node P and the third inductor L23. In the example shown in FIG. 1, the parallel resonant circuit 21 includes the fourth inductor L24 and the capacitor C28.

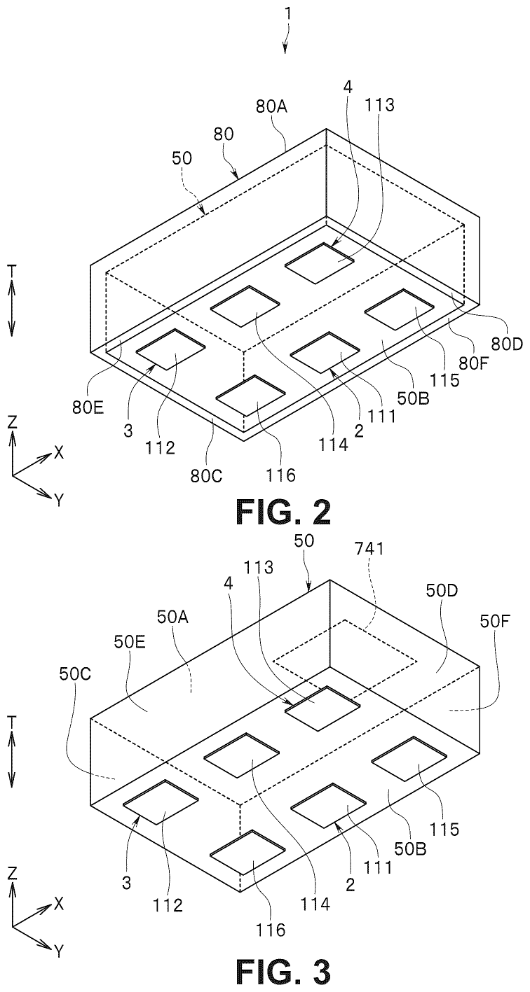

Reference is now made to FIG. 2 and FIG. 3 to describe other configurations of the electronic component 1. FIG. 2 is a perspective view showing an appearance of the electronic component 1. FIG. 3 is a perspective view showing a stack of the electronic component 1.

The electronic component 1 includes a stack 50. The stack 50 includes a plurality of dielectric layers stacked together and a plurality of conductors (a plurality of conductor layers and a plurality of through holes). The common terminal 2, the first signal terminal 3, the second signal terminal 4, the first filter 10, and the second filter 20 are integrated into the stack 50.

The stack 50 has a first surface 50A and a second surface 50B located at both respective ends in a stacking direction T of the plurality of dielectric layers, and four side surfaces 50C to 50F connecting the first surface 50A and the second surface 50B. The side surfaces 50C and 50D are opposite to each other. The side surfaces 50E and 50F are opposite to each other. The side surfaces 50C to 50F may be perpendicular to the first surface 50A and the second surface 50B.

Here, as shown in FIG. 2 and FIG. 3, an X direction, a Y direction, and a Z direction are defined. The X direction, the Y direction, and the Z direction are orthogonal to one another. In the example embodiment, a direction in parallel to the stacking direction T is defined as the Z direction. A direction opposite to the X direction is defined as a-X direction, a direction opposite to the Y direction is defined as a-Y direction, and a direction opposite to the Z direction is defined as a-Z direction. The expression “when seen from a predetermined direction (for example, the stacking direction T)” may mean to see an object from a position away in the predetermined direction or one direction parallel to the predetermined direction.

As shown in FIG. 3, the first surface 50A is located at the end of the stack 50 in the Z direction. The first surface 50A is also the top surface of the stack 50. The second surface 50B is located at the end of the stack 50 in the −Z direction. The second surface 50B is also the bottom surface of the stack 50. The side surface 50C is located at the end of the stack 50 in the −X direction. The side surface 50D is located at the end of the stack 50 in the X direction. The side surface 50E is located at the end of the stack 50 in the −Y direction. The side surface 50F is located at the end of the stack 50 in the Y direction.

As shown in FIG. 2 and FIG. 3, the electronic component 1 further includes electrodes 111, 112, and 113 provided on the second surface 50B of the stack 50. The electrode 111 is arranged at a position closer to the side surface 50F than to the side surface 50E. The electrodes 112 and 113 are arranged at positions closer to the side surface 50E than to the side surface 50F. The electrode 112 is arranged near a corner portion located where the side surface 50C and the side surface 50E intersect, and the electrode 113 is arranged near a corner portion located where the side surface 50D and the side surface 50E intersect. The electrode 111 corresponds to the common terminal 2, the electrode 112 corresponds to the first signal terminal 3, and the electrode 113 corresponds to the second signal terminal 4. The common terminal 2 and the first and second signal terminals 3 and 4 are thus provided to the second surface 50B of the stack 50.

The electronic component 1 further includes electrodes 114, 115, and 116 provided to the second surface 50B of the stack 50. The electrode 114 is arranged between the electrode 112 and the electrode 113. The electrode 115 is arranged between the electrode 111 and the side surface 50D. The electrode 116 is arranged between the electrode 111 and the side surface 50C. Each of the electrodes 114, 115, and 116 is connected to the ground.

The electronic component 1 further includes a shield conductor 80 formed of a conductor and integrated into the stack 50. The shield conductor 80 includes a first conductor part 80E provided to the side surface 50E of the stack 50 and a second conductor part 80F provided to the side surface 50F of the stack 50. Particularly in the example embodiment, the first conductor part 80E covers the entire or approximately the entire side surface 50E. The second conductor part 80F covers the entire or approximately the entire side surface 50F.

The shield conductor 80 further includes a conductor part 80A provided to the first surface 50A of the stack 50, a conductor part 80C provided to the side surface 50C of the stack 50, and a conductor part 80D provided to the side surface 50D of the stack 50. Particularly in the example embodiment, the conductor part 80A covers the entire first surface 50A. The conductor part 80C covers the entire or approximately the entire side surface 50C. The conductor part 80D covers the entire or approximately the entire side surface 50D.

The shield conductor 80 may include a plurality of metal layers stacked together. In this case, the first conductor part 80E, the second conductor part 80F, and the conductor parts 80A, 80C, and 80D are preferably contiguous. In other words, each of the first and second conductor parts 80E and 80F is preferably connected to the conductor parts 80A, 80C, and 80D.

The shield conductor 80 is electrically connected to the electrodes 114, 115, and 116. The stack 50 includes a plurality of conductors electrically connecting the shield conductor 80 and the electrodes 114, 115, and 116.

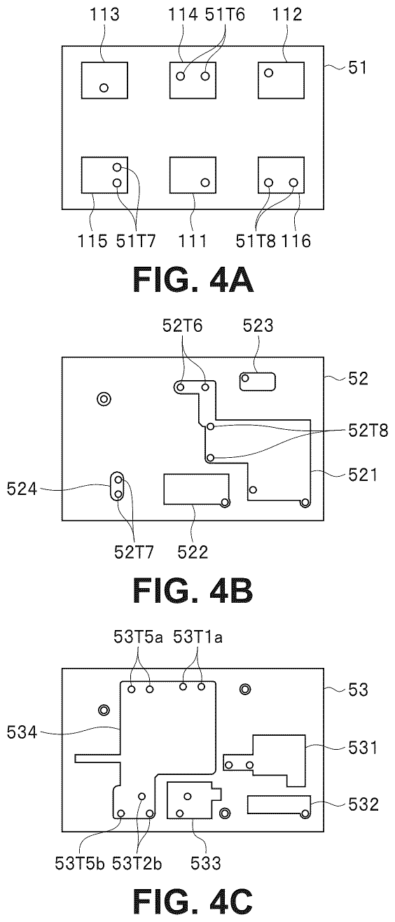

Next, with reference to FIG. 4A to FIG. 11, an example of the plurality of dielectric layers and the plurality of conductors constituting the stack 50 will be described. In this example, the stack 50 includes twenty-four dielectric layers stacked together. The twenty-four dielectric layers are hereinafter referred to as first to twenty-fourth dielectric layers in the order from bottom to top. The first to twenty-fourth dielectric layers are denoted by reference numerals 51 to 74.

In FIG. 4A to FIG. 10B, each circle represents a through hole. A plurality of through holes are formed in each of the dielectric layers 51 to 72. The plurality of through holes are each formed by filling conductive paste in a hole for a through hole. Each of the plurality of through holes is connected to an electrode, a conductor layer, or another through hole. In the following description, for a connection relationship between each of the plurality of through holes and the electrode, the conductor layer, or the other through hole, the connection relationship in a state where the first to twenty-fourth dielectric layers 51 to 74 are stacked together will be described. In FIG. 4A to FIG. 10B, a plurality of specific through holes among the plurality of through holes are denoted by respective reference signs.

FIG. 4A shows a patterned surface of the first dielectric layer 51. The electrodes 111 to 116 are formed on the patterned surface of the dielectric layer 51.

In FIG. 4A, two through holes denoted by a reference sign 51T6 are connected to the electrode 114. Note that, in the following description, the through hole denoted by the reference sign 51T6 will be referred to simply as a through hole 51T6. Each through hole denoted by a reference sign other than the through hole 51T6 will be referred to similarly as the through hole 51T6.

Two through 51T7 shown in FIG. 4A are connected to the electrode 115. Two through holes 51T8 shown in FIG. 4A are connected to the electrode 116.

FIG. 4B shows a patterned surface of the second dielectric layer 52. Conductor layers 521, 522, 523, and 524 are formed on the patterned surface of the dielectric layer 52. The two through holes 51T6 and the two through holes 51T8 and two through holes 52T6 and two through holes 52T8 shown in FIG. 4B are connected to the conductor layer 521. The two through holes 51T7 and two through holes 52T7 shown in FIG. 4B are connected to the conductor layer 524.

FIG. 4C shows a patterned surface of the third dielectric layer 53. Conductor layers 531, 532, 533, and 534 are formed on the patterned surface of the dielectric layer 53. The two through holes 52T6, the two through holes 52T7, and the two through holes 52T8 and two through holes 53T1a, two through holes 53T2b, two through holes 53T5a, and a through hole 53T5b shown in FIG. 4C are connected to the conductor layer 534.

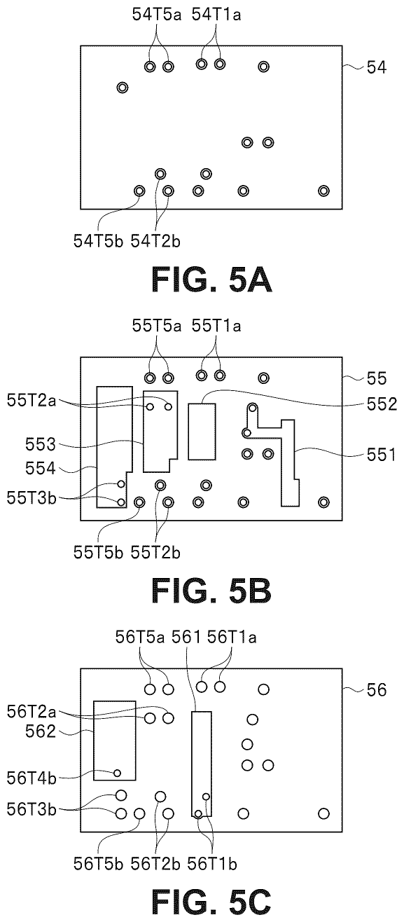

FIG. 5A shows a patterned surface of the fourth dielectric layer 54. The two through holes 53T1a, the two through holes 53T2b, and the two through holes 53T5a, and the through hole 53T5b are connected respectively to two through holes 54T1a, two through holes 54T2b, two through holes 54T5a, and a through hole 54T5b shown in FIG. 5A.

FIG. 5B shows a patterned surface of the fifth dielectric layer 55. Conductor layers 551, 552, 553, and 554 are formed on the patterned surface of the dielectric layer 55. The two through holes 54T1a, the two through holes 54T2b, the two through holes 54T5a, and the through hole 54T5b are connected respectively to two through holes 55T1a, two through holes 55T2b, two through holes 55T5a, and a through hole 55T5b shown in FIG. 5B. Two through holes 55T2a shown in FIG. 5B are connected to the conductor layer 553. Two through holes 55T3b sown in FIG. 5B are connected to the conductor layer 554.

FIG. 5C shows a patterned surface of the sixth dielectric layer 56. Conductor layers 561 and 562 are formed on the patterned surface of the dielectric layer 56. The two through holes 55T1a, the two through holes 55T2a, the two through holes 55T2b, the two through holes 55T3b, the two through holes 55T5a, and the through hole 55T5b are connected respectively to two through holes 56T1a, two through holes 56T2a, two through holes 56T2b, two through holes 56T3b, two through holes 56T5a, and a through hole 56T5b shown in FIG. 5C. Two through holes 56T1b shown in FIG. 5C are connected to the conductor layer 561. The through hole 56T4b shown in FIG. 5C is connected to the conductor layer 562.

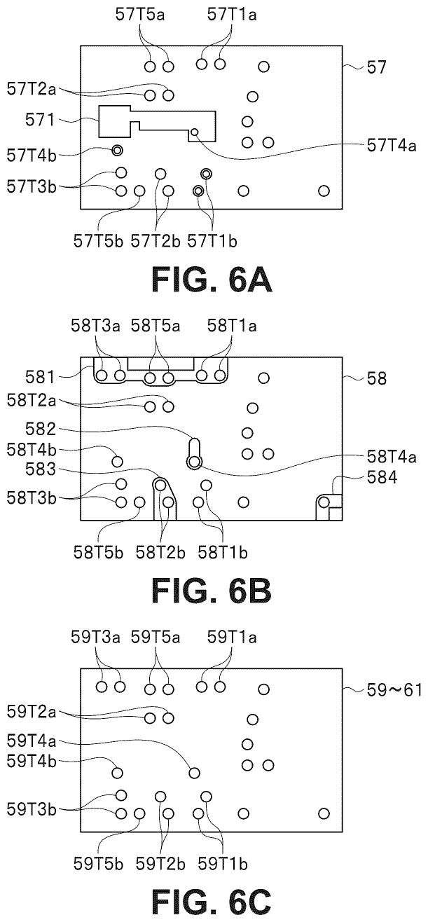

FIG. 6A shows a patterned surface of the seventh dielectric layer 57. A conductor layer 571 is formed on the patterned surface of the dielectric layer 57. The two through holes 56T1a, the two through holes 56T1b, the two through holes 56T2a, the two through holes 56T2b, the two through holes 56T3b, the through hole 56T4b, the two through holes 56T5a, and the through hole 56T5b are connected respectively to two through holes 57T1a, two through holes 57T1b, two through holes 57T2a, two through holes 57T2b, two through holes 57T3b, a through hole 57T4b, two through holes 57T5a, and a through hole 57T5b shown in FIG. 6A. A through hole 57T4a shown in FIG. 6A is connected to the conductor layer 571.

FIG. 6B shows a patterned surface of the eighth dielectric layer 58. Conductor layers 581, 582, 583, and 584 are formed on the patterned surface of the dielectric layer 58. The conductor layer 581 is connected to the first conductor part 80E of the shield conductor 80 (see FIG. 2). The conductor layer 583 is connected to the second conductor part 80F of the shield conductor 80 (see FIG. 2). The conductor layer 584 is connected to the second conductor part 80F and the conductor part 80C of the shield conductor 80 (see FIG. 2).

The two through holes 57T1a and the two through holes 57T5a and two through holes 58T1a, two through holes 58T3a, and two through holes 58T5a shown in FIG. 6B are connected to the conductor layer 581. The two through holes 57T1b, the two through holes 57T2a, the two through holes 57T3b, the through hole 57T4b, and the through hole 57T5b are connected respectively to two through holes 58T1b, two through holes 58T2a, two through holes 58T3b, a through hole 58T4b, and a through hole 58T5b shown in FIG. 6B. The two through holes 57T2b and two through holes 58T2b shown in FIG. 6B are connected to the conductor layer 583. The through hole 57T4a and a through hole 58T4a shown in FIG. 6B are connected to the conductor layer 582.

FIG. 6C shows a patterned surface of each of the ninth to eleventh dielectric layers 59 to 61. The two through holes 58T1a, the two through holes 58T1b, the two through holes 58T2a, the two through holes 58T2b, the two through holes 58T3a, the two through holes 58T3b, the two through holes 58T5a, and the through hole 58T5b are connected respectively to two through holes 59T1a, two through holes 59T1b, two through holes 59T2a, two through holes 59T2b, two through holes 59T3a, two through hole 59T3b, two through holes 59T5a, and a through hole 59T5b formed in the dielectric layer 59. The through holes 58T4a and 58T4b are connected respectively to through holes 59T4a and 59T4b formed in the dielectric layer 59. In the dielectric layers 59 to 61, vertically connected through holes denoted by the same reference signs are connected to each other.

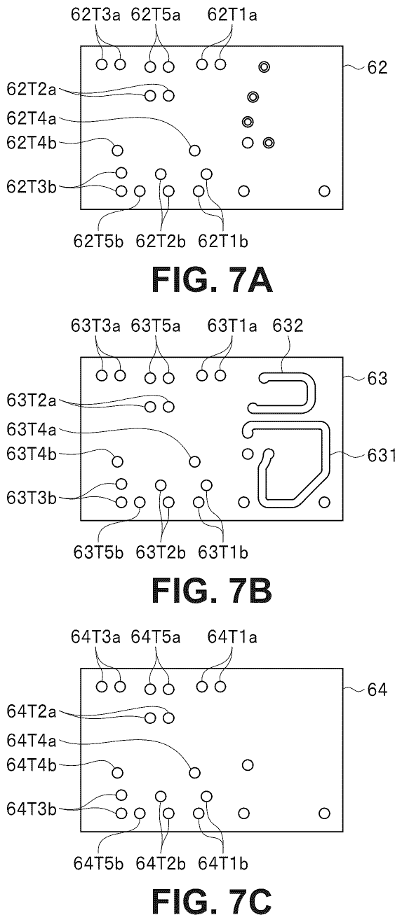

FIG. 7A shows a patterned surface of the twelfth dielectric layer 62. The two through holes 59T1a, the two through holes 59T1b, the two through holes 59T2a, the two through holes 59T2b, the two through holes 59T3a, the two through hole 59T3b, the two through holes 59T5a, and the through hole 59T5b formed in the dielectric layer 61 are connected respectively to two through holes 62T1a, two through holes 62T1b, two through holes 62T2a, two through holes 62T2b, two through holes 62T3a, two through hole 62T3b, two through holes 62T5a, and a through hole 62T5b shown in FIG. 7A. The through holes 59T4a and 59T4b formed in the dielectric layer 61 are connected respectively to through holes 62T4a and 62T4b shown in FIG. 7A.

FIG. 7B shows a patterned surface of the thirteenth dielectric layer 63. Inductor conductor layers 631 and 632 are formed on the patterned surface of the dielectric layer 63. The two through holes 62T1a, the two through holes 62T1b, the two through holes 62T2a, the two through holes 62T2b, the two through holes 62T3a, the two through holes 62T3b, the two through holes 62T5a, and the through hole 62T5b are connected respectively to two through holes 63T1a, two through holes 63T1b, two through holes 63T2a, two through holes 63T2b, two through holes 63T3a, two through holes 63T3b, two through holes 63T5a, and a through hole 63T5b shown in FIG. 7B. The through holes 62T4a and 62T4b are connected respectively to through holes 63T4a and 63T4b shown in FIG. 7B.

FIG. 7C shows a patterned surface of the fourteenth dielectric layer 64. The two through holes 63T1a, the two through holes 63T1b, the two through holes 63T2a, the two through holes 63T2b, the two through holes 63T3a, the two through holes 63T3b, the two through holes 63T5a, and the through hole 63T5b are connected respectively to two through holes 64T1a, two through holes 64T1b, two through holes 64T2a, two through holes 64T2b, two through holes 64T3a, two through holes 64T3b, two through holes 64T5a, and a through hole 64T5b shown in FIG. 7C. The through holes 63T4a and 63T4b are connected respectively to through holes 64T4a and 64T4b shown in FIG. 7C.

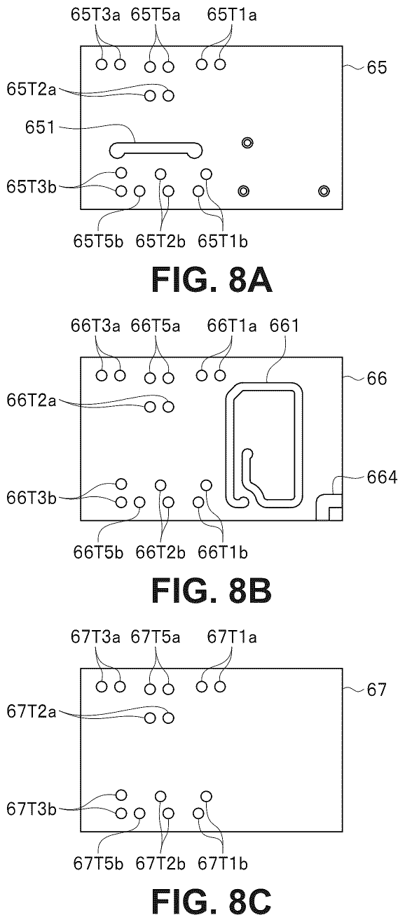

FIG. 8A shows a patterned surface of the fifteenth dielectric layer 65. An inductor conductor layer 651 is formed on the patterned surface of the dielectric layer 65. The conductor layer 651 has a first end and a second end located at both respective longitudinal-direction ends of the conductor layer 651. The through hole 64T4a is connected to a portion of the conductor layer 651 near the first end. The through hole 64T4b is connected to a portion of the conductor layer 651 near the second end.

The two through holes 64T1a, the two through holes 64T1b, the two through holes 64T2a, the two through holes 64T2b, the two through holes 64T3a, the two through holes 64T3b, the two through holes 64T5a, and the through hole 64T5b are connected respectively to two through holes 65T1a, two through holes 65T1b, two through holes 65T2a, two through holes 65T2b, two through holes 65T3a, two through holes 65T3b, two through holes 65T5a, and a through hole 65T5b shown in FIG. 8A.

FIG. 8B shows a patterned surface of the sixteenth dielectric layer 66. An inductor conductor layer 661 and a conductor layer 664 are formed on the patterned surface of the dielectric layer 66. The conductor layer 664 is connected to the second conductor part 80F and the conductor part 80C of the shield conductor 80 (see FIG. 2).

The two through holes 65T1a, the two through holes 65T1b, the two through holes 65T2a, the two through holes 65T2b, the two through holes 65T3a, the two through holes 65T3b, the two through holes 65T5a, and the through hole 65T5b are connected respectively to two through holes 66T1a, two through holes 66T1b, two through holes 66T2a, two through holes 66T2b, two through holes 66T3a, two through holes 66T3b, two through holes 66T5a, and a through hole 66T5b shown in FIG. 8B.

FIG. 8C shows a patterned surface of the seventeenth dielectric layer 67. The two through holes 66T1a, the two through holes 66T1b, the two through holes 66T2a, the two through holes 66T2b, the two through holes 66T3a, the two through holes 66T3b, the two through holes 66T5a, and the through hole 66T5b are connected respectively to two through holes 67T1a, two through holes 67T1b, two through holes 67T2a, two through holes 67T2b, two through holes 67T3a, two through holes 67T3b, two through holes 67T5a, and a through hole 67T5b shown in FIG. 8C.

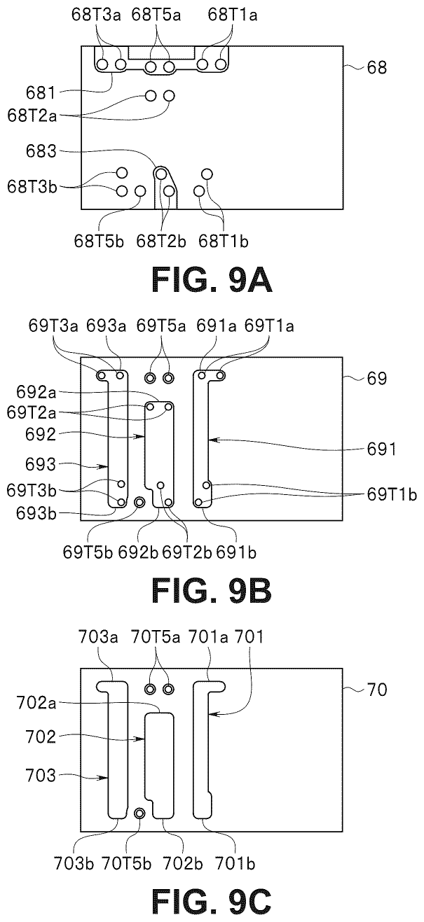

FIG. 9A shows a patterned surface of the eighteenth dielectric layer 68. Conductor layers 681 and 683 are formed on the patterned surface of the dielectric layer 68. The conductor layer 681 is connected to the first conductor part 80E of the shield conductor 80 (see FIG. 2). The conductor layer 683 is connected to the second conductor part 80F of the shield conductor 80 (see FIG. 2).

The two through holes 67T1a, the two through holes 67T3a, and the two through holes 67T5a and two through holes 68T1a, two through holes 68T3a, and two through holes 68T5a shown in FIG. 9A are connected to the conductor layer 681. The two through holes 67T1b, the two through holes 67T2a, the two through holes 67T3b, and the through hole 67T5b are connected respectively to two through holes 68T1b, two through holes 68T2a, two through holes 68T3b, and a through hole 68T5b shown in FIG. 9A. The two through holes 67T2b and two through holes 68T2b shown in FIG. 9A are connected to the conductor layer 683.

FIG. 9B shows a patterned surface of the nineteenth dielectric layer 69. Inductor conductor layers 691, 692, 693 are formed on the patterned surface of the dielectric layer 69. The conductor layer 691 has a first end 691a and a second end 691b located at both respective longitudinal-direction ends of the conductor layer 691. The conductor layer 692 has a first end 692a and a second end 692b located at both respective longitudinal-direction ends of the conductor layer 692. The conductor layer 693 has a first end 693a and a second end 693b located at both respective longitudinal-direction ends of the conductor layer 693. Each of the first ends 691a, 692a, and 693a is at a position closer to the first conductor part 80E of the shield conductor 80 (upper position in FIG. 9B) than to the second conductor part 80F of the shield conductor 80. Each of the second ends 691b, 692b, and 693b is at a position closer to the second conductor part 80F of the shield conductor 80 (lower position in FIG. 9B) than to the first conductor part 80E of the shield conductor 80.

The two through holes 68T1a and two through holes 69T1a shown in FIG. 9B are connected to portions of the conductor layer 691 near the first end 691a. The two through holes 68T1b and two through holes 69T1b shown in FIG. 9B are connected to portions of the conductor layer 691 near the second end 691b. The two through holes 68T2a and two through holes 69T2a shown in FIG. 9B are connected to portions of the conductor layer 692 near the first end 692a. The two through holes 68T2b and two through holes 69T2b shown in FIG. 9B are connected to portions of the conductor layer 692 near the second end 692b. The two through holes 68T3a and two through holes 69T3a shown in FIG. 9B are connected to portions of the conductor layer 693 near the first end 693a. The two through holes 68T3b and two through holes 69T3b shown in FIG. 9B are connected to portions of the conductor layer 693 near the second end 693b. The two through holes 68T5a and the through hole 68T5b are connected respectively to two through holes 69T5a and a through hole 69T5b shown in FIG. 9B.

FIG. 9C shows a patterned surface of the twentieth dielectric layer 70.

Inductor conductor layers 701, 702, and 703 are formed on the patterned surface of the dielectric layer 70. The conductor layer 701 has a first end 701a and a second end 701b located at both respective longitudinal-direction ends of the conductor layer 701. The conductor layer 702 has a first end 702a and a second end 702b located at both respective longitudinal-direction ends of the conductor layer 702. The conductor layer 703 has a first end 703a and a second end 703b located at both respective longitudinal-direction ends of the conductor layer 703. Each of the first ends 701a, 702a, and 703a is at a position closer to the first conductor part 80E of the shield conductor 80 (upper position in FIG. 9C) than to the second conductor part 80F of the shield conductor 80. Each of the second ends 701b, 702b, and 703b is at a position closer to the second conductor part 80F of the shield conductor 80 (lower position in FIG. 9C) than to the first conductor part 80E of the shield conductor 80.

The two through holes 69T1a are connected to portions of the conductor layer 701 near the first end 701a. The two through holes 69T1b are connected to portions of the conductor layer 701 near the second end 701b. The two through holes 69T2a are connected to portions of the conductor layer 702 near the first end 702a. The two through holes 69T2b are connected to portions of the conductor layer 702 near the second end 702b. The two through holes 69T3a are connected to portions of the conductor layer 703 near the first end 703a. The two through holes 69T3b are connected to portions of the conductor layer 703 near the second end 703b. The two through holes 69T5a and the through hole 69T5b are connected respectively to two through holes 70T5a and a through hole 70T5b shown in FIG. 9C.

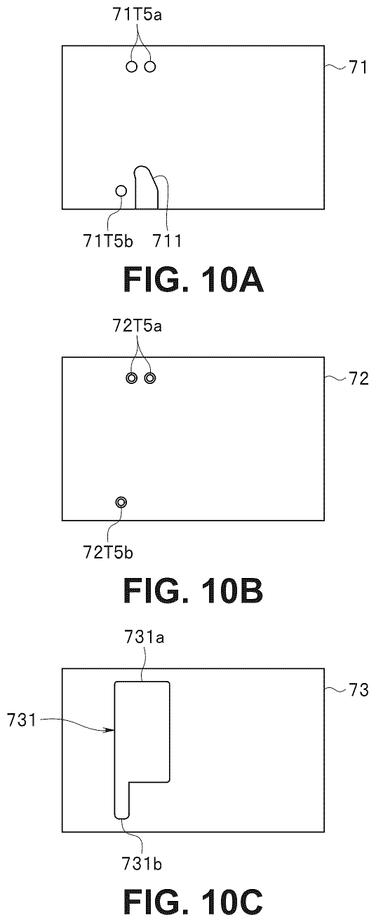

FIG. 10A shows a patterned surface of the twenty-first dielectric layer 71. A conductor layer 711 is formed on the patterned surface of the dielectric layer 71. The conductor layer 711 is connected to the second conductor part 80F of the shield conductor 80 (see FIG. 2). The two through holes 70T5a and the through hole 70T5b are connected respectively to two through holes 71T5a and a through hole 71T5b shown in FIG. 10A.

FIG. 10B shows a patterned surface of the twenty-second dielectric layer 72. The two through holes 71T5a and the through hole 71T5b are connected respectively to two through holes 72T5a and a through hole 72T5b shown in FIG. 10B.

FIG. 10C shows a patterned surface of the twenty-third dielectric layer 73. A conductor layer 731 is formed on the patterned surface of the dielectric layer 73. The conductor layer 731 has a first end 731a and a second end 731b located at both respective longitudinal-direction ends of the conductor layer 731. The first end 731a is at a position closer to the first conductor part 80E of the shield conductor 80 (upper position in FIG. 10C) than to the second conductor part 80F of the shield conductor 80. The second end 731b is at a position closer to the second conductor part 80F of the shield conductor 80 (lower position in FIG. 10C) than to the first conductor part 80E of the shield conductor 80.

The two through holes 72T5a are connected to portions of the conductor layer 731 near the first end 731a. The through hole 72T5b is connected to a portion of the conductor layer 731 near the second end 731b.

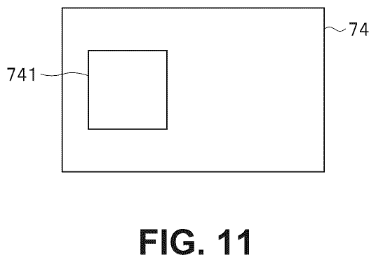

FIG. 11 shows a patterned surface of the twenty-fourth dielectric layer 74. A mark 741 is formed on the patterned surface of the dielectric layer 74.

The stack 50 shown in FIG. 2 is formed by stacking the first to twenty-fourth dielectric layers 51 to 74 such that the patterned surface of the first dielectric layer 51 serves as the second surface 50B of the stack 50 and the surface of the twenty-fourth dielectric layer 74 opposite to the patterned surface thereof serves as the first surface 50A of the stack 50.

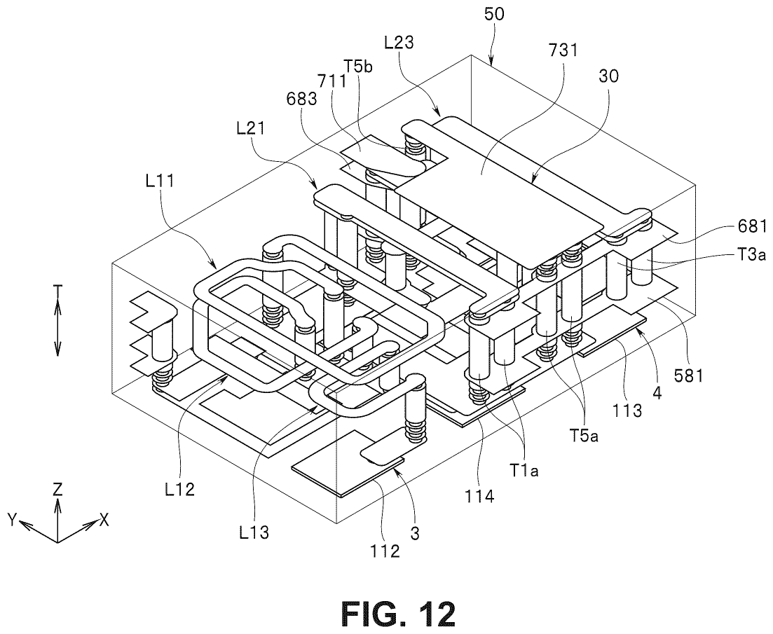

FIG. 12 shows an internal structure of the stack 50 formed by stacking the first to twenty-fourth dielectric layers 51 to 74. As shown in FIG. 12, in the internal structure of the stack 50, the plurality of conductor layers and the plurality of through holes shown in FIG. 4A to FIG. 10C are stacked. Note that the mark 741 is omitted in FIG. 12.

Correspondence between the components of the circuit of the electronic component 1 shown in FIG. 1 and the components of the internal structure of the stack 50 shown in FIG. 4A to FIG. 11 will be described below. First, the first filter 10 will be described.

The inductor L11 is formed of the inductor conductor layer 661. The inductor L12 is formed of the inductor conductor layer 631. The inductor L13 is formed of the inductor conductor layer 632.

The capacitor C11 is formed of the conductor layers 521 and 531 and the dielectric layer 52 between these conductor layers. The capacitor C12 is formed of the conductor layers 532 and 551 and the dielectric layers 53 and 54 between these conductor layers. The capacitor C13 is formed of the conductor layers 531 and 551 and the dielectric layers 53 and 54 between these conductor layers.

Next, components of the second filter 20 will be described. The first inductor L21 is formed of the inductor conductor layers 691 and 701 and the through holes 53T1a, 54T1a, 55T1a, 56T1a, 56T1b, 57T1a, 57T1b, 58T1a, 58T1b, 59T1a, 59T1b, 62T1a, 62T1b, 63T1a, 63T1b, 64T1a, 64T1b, 65T1a, 65T1b, 66T1a, 66T1b, 67T1a, 67T1b, 68T1a, 68T1b, 69T1a, and 69T1b.

The second inductor L22 is formed of the inductor conductor layers 692 and 702 and the through holes 53T2b, 54T2b, 55T2a, 55T2b, 56T2a, 56T2b, 57T2a, 57T2b, 58T2a, 58T2b, 59T2a, 59T2b, 62T2a, 62T2b, 63T2a, 63T2b, 64T2a, 64T2b, 65T2a, 65T2b, 66T2a, 66T2b, 67T2b, 68T2a, 68T2b, 69T2a, and 69T2b.

The third inductor L23 is formed of the inductor conductor layers 693 and 703 and the through holes 55T3b, 56T3b, 57T3b, 58T3a, 58T3b, 59T3b, 62T3a, 62T3b, 63T3a, 63T3b, 64T3a, 64T3b, 65T3a, 65T3b, 66T3a, 66T3b, 67T3a, 67T3b, 68T3a, 68T3b, 69T3a, and 69T3b.

The fourth inductor L24 is formed of the inductor conductor layer 651, the conductor layer 582, and the through holes 56T4b, 57T4a, 57T4b, 58T4a, 58T4b, 59T4a, 59T4b, 62T4a, 62T4b, 63T4a, 63T4b, 64T4a, and 64T4b.

The capacitor C21 is formed of the conductor layers 522 and 533 and the dielectric layer 52 between these conductor layers. The capacitor C22 is formed of the conductor layers 561 and 571 and the dielectric layer 56 between these conductor layers. The capacitor C23 is formed of the conductor layers 534, 552, and 561 and the dielectric layers 53 to 55 between these conductor layers. The capacitor C24 is formed of the conductor layers 553 and 571 and the dielectric layers 55 and 56 between these conductor layers. The capacitor C25 is formed of the conductor layers 534 and 553 and the dielectric layers 53 and 54 between these conductor layers.

The capacitor C26 is formed of the conductor layers 554 and 562 and the dielectric layer 55 between these conductor layers. The capacitor C27 is formed of the conductor layers 534 and 554 and the dielectric layers 53 and 54 between these conductor layers. The capacitor C28 is formed of the conductor layers 562 and 571 and the dielectric layer 56 between these conductor layers.

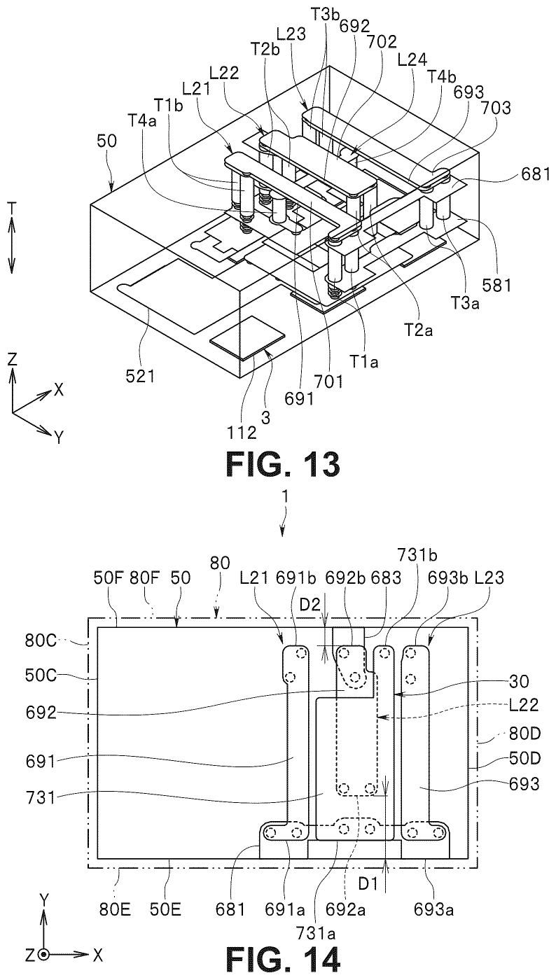

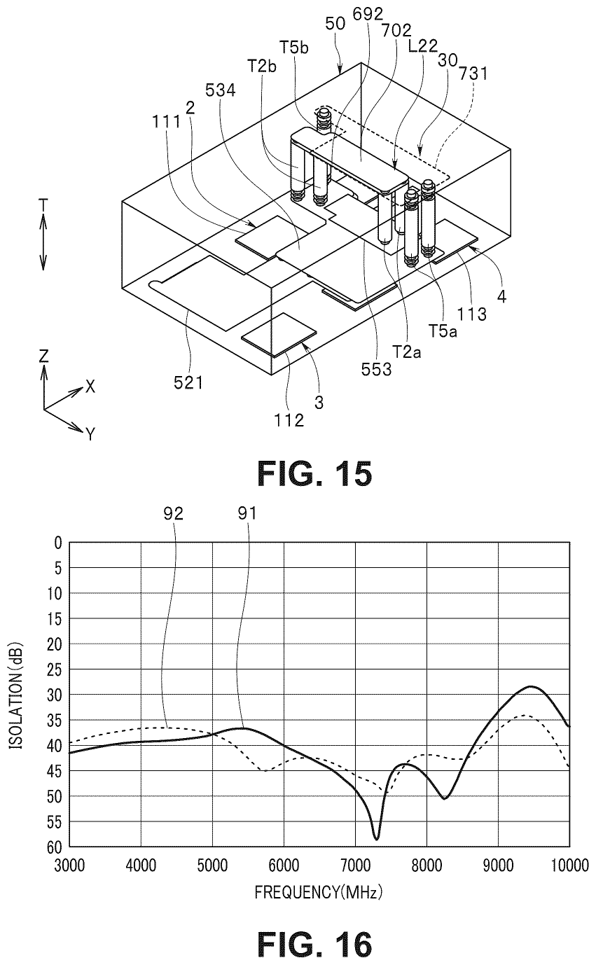

Reference is now made to FIG. 1 to FIG. 15 to describe structural features of the electronic component 1 according to the example embodiment. FIG. 13 is a perspective view showing part of an internal structure of the electronic component 1. Note that the first to fourth inductors L21 to L24 of the second filter 20 are shown in FIG. 13 among the components of the electronic component 1 shown in FIG. 1. FIG. 14 is a plan view showing part of the internal structure of the electronic component 1. Note that FIG. 14 shows an internal structure of the stack 50 when seen from the first surface 50A side of the stack 50. Moreover, in FIG. 14, the conductor part 80A of the shield conductor 80 (see FIG. 2) is omitted. FIG. 15 is a perspective view showing part of an internal structure of the electronic component 1. Note that the second inductor L22 and a ground structure to be described later are shown in FIG. 15.

First, features related to the first to third inductors L21, L22, and L23 of the second filter 20 will be described. As shown in FIG. 13 and FIG. 14, the second inductor L22 is arranged between the first inductor L21 and the third inductor L23. The first to third inductors L21, L22, and L23 are arranged in this order from the side surface 50C of the stack 50 toward the side surface 50D of the stack 50.

The first to third inductors L21, L22, and L23 are each an inductor wound around an axis extending in a direction orthogonal to the stacking direction T. Here, a columnar structure formed with a plurality of through holes being connected in series is referred to as a columnar conductor. The columnar conductor extends in a direction parallel to the stacking direction T. Each of the first to third inductors L21, L22, and L23 includes at least one conductor layer and a plurality of columnar conductors.

Each of the first to third inductors L21, L22, and L23 is also a rectangular or approximately rectangular winding. For the rectangular or approximately rectangular winding, the number of windings may be counted, when the winding is regarded as a rectangle, as ¼ per side of the rectangle. In the example embodiment, each of the first to third inductors L21, L22, and L23 has the number of windings of ¾.

The first inductor L21 includes two columnar conductors T1a and two columnar inductors T1b each extending in the stacking direction T and the inductor conductor layer 691 connecting the two columnar conductors T1a and the two columnar conductors T1b. The conductor layer 691 extends along a plane intersecting the stacking direction T, i.e., the patterned surface of the dielectric layer 69. In the example embodiment, the conductor layer 691 extends from the side surface 50E toward the side surface 50F. The two columnar conductors T1a are connected to portions of the conductor layer 691 near the first end 691a. The two columnar conductors T1b are connected to portions of the conductor layer 691 near the second end 691b.

The two columnar conductors T1a are formed by connecting the through holes 53T1a, 54T1a, 55T1a, 56T1a, 57T1a, 58T1a, 59T1a, 62T1a, 63T1a, 64T1a, 65T1a, 66T1a, 67T1a, and 68T1a in series. The two columnar conductors T1b are formed by connecting the through holes 56T1b, 57T1b, 58T1b, 59T1b, 62T1b, 63T1b, 64T1b, 65T1b, 66T1b, 67T1b, and 68T1b in series.

The two columnar conductors T1a are connected to the first conductor part 80E of the shield conductor 80 via the conductor layers 581 and 681. The two columnar conductors T1a are connected to the electrodes 114, 115, and 116 connected to the ground via the conductor layer 534, the through holes 52T6, 52T7, and 52T8, the conductor layers 521 and 524, and the through holes 51T6, 51T7, and 51T8.

The first inductor L21 is wound around a first axis orthogonal to the stacking direction T so as to form a first opening surrounded by the conductor layer 691, the two columnar conductors T1a, and the two columnar conductors T1b. The first axis may extend in a direction parallel to the X direction.

The first inductor L21 further includes the conductor layer 701 and the through holes 69T1a and 69T1b electrically connecting the conductor layer 691 and the conductor layer 701. The conductor layer 701 extends from the side surface 50E toward the side surface 50F.

The second inductor L22 includes two columnar conductors T2a and two columnar inductors T2b each extending in the stacking direction T and the conductor layer 692 connecting the two columnar conductors T2a and the two columnar conductors T2b. The conductor layer 692 extends along a plane intersecting the stacking direction T, i.e., the patterned surface of the dielectric layer 69. In the example embodiment, the conductor layer 692 extends from the side surface 50E toward the side surface 50F. The two columnar conductors T2a are connected to portions of the conductor layer 692 near the first end 692a. The two columnar conductors T2b are connected to portions of the conductor layer 692 near the second end 692b.

The two columnar conductors T2a are formed by connecting the through holes 55T2a, 56T2a, 57T2a, 58T2a, 59T2a, 62T2a, 63T2a, 64T2a, 65T2a, 66T2a, 67T2a, and 68T2a in series. The two columnar conductors T2b are formed by connecting the through holes 53T2b, 54T2b, 55T2b, 56T2b, 57T2b, 58T2b, 59T2b, 62T2b, 63T2b, 64T2b, 65T2b, 66T2b, 67T2b, and 68T2b in series.

The two columnar conductors T2b are connected to the second conductor part 80F of the shield conductor 80 via the conductor layers 583 and 683. The two columnar conductors T2b are connected to the electrodes 114, 115, and 116 connected to the ground via the conductor layer 534, the through holes 52T6, 52T7, and 52T8, the conductor layers 521 and 524, and the through holes 51T6, 51T7, and 51T8.

The second inductor L22 is wound around a second axis orthogonal to the stacking direction T so as to form a second opening surrounded by the conductor layer 692, the two columnar conductors T2a, and the two columnar conductors T2b. The second axis may extend in a direction parallel to the X direction.

The second inductor L22 further includes the conductor layer 702 and the through holes 69T2a and 69T2b electrically connecting the conductor layer 692 and the conductor layer 702. The conductor layer 702 extends from the side surface 50E toward the side surface 50F.

The third inductor L23 includes two columnar conductors T3a and two columnar inductors T3b each extending in the stacking direction T and the conductor layer 693 connecting the two columnar conductors T3a and the two columnar conductors T3b. The conductor layer 693 extends along a plane intersecting the stacking direction T, i.e., the patterned surface of the dielectric layer 69. In the example embodiment, the conductor layer 693 extends from the side surface 50E toward the side surface 50F. The two columnar conductors T3a are connected to portions of the conductor layer 693 near the first end 693a. The two columnar conductors T3b are connected to portions of the conductor layer 693 near the second end 693b.

The two columnar conductors T3a are formed by connecting the through holes 58T3a, 59T3a, 62T3a, 63T3a, 64T3a, 65T3a, 66T3a, 67T3a, and 68T3a in series. The two columnar conductors T3b are formed by connecting the through holes 55T3b, 56T3b, 57T3b, 58T3b, 59T3b, 62T3b, 63T3b, 64T3b, 65T3b, 66T3b, 67T3b, and 68T3b in series.

The two columnar conductors T3a are connected to the first conductor part 80E of the shield conductor 80 via the conductor layers 581 and 681. The two columnar conductors T3a are connected to the electrodes 114, 115, and 116 connected to the ground via the conductor layer 534, the through holes 52T6, 52T7, and 52T8, the conductor layers 521 and 524, and the through holes 51T6, 51T7, and 51T8.

The third inductor L23 is wound around a third axis orthogonal to the stacking direction T so as to form a third opening surrounded by the conductor layer 693, the two columnar conductors T3a, and the two columnar conductors T3b. The third axis may extend in a direction parallel to the X direction.

The third inductor L23 further includes the conductor layer 703 and the through holes 69T3a and 69T3b electrically connecting the conductor layer 693 and the conductor layer 703. The conductor layer 703 extends from the side surface 50E toward the side surface 50F.

Here, the winding direction of an inductor is defined as a direction from one end of the inductor toward the other end of the inductor. The one end of the inductor is an end portion furthest from the ground in the circuit configuration, and the other end of the inductor is an end portion closest to the ground in the circuit configuration. The winding direction of the first inductor L21 is a direction from the two through holes 56T1b toward the two through holes 53T1a via the two columnar conductors T1b, the conductor layer 691, and the two columnar conductors T1a in this order. The winding direction of the second inductor L22 is a direction from the two through holes 55T2a toward the two through holes 53T2b via the two columnar conductors T2a, the conductor layer 692, and the two columnar conductors T2b in this order. The winding direction of the third inductor L23 is a direction from the two through holes 55T3b toward the two through holes 58T3a via the two columnar conductors T3b, the conductor layer 693, and the two columnar conductors T3a in this order.

The first to third inductors L21, L22, and L23 are arranged so that the first opening of the first inductor L21, the second opening of the second inductor L22, and the third opening of the third inductor L23 overlap when seen in a direction parallel to the X direction. The winding direction of the third inductor L23 is the same direction as the winding direction of the first inductor L21 when seen in the X direction. The winding direction of the second inductor L22 is a direction opposite to the winding direction of each of the first and third inductors L21 and L23 when seen in the X direction.

Next, features related to the first to third inductors L21, L22, and L23 and the shield conductor 80 will be described. As described above, the first end 692a of the conductor layer 692 of the second inductor L22 is at a position closer to the first conductor part 80E of the shield conductor 80 than to the second conductor part 80F of the shield conductor 80, and the second end 692b of the conductor layer 692 of the second inductor L22 is at a position closer to the second conductor part 80F of the shield conductor 80 than to the first conductor part 80E of the shield conductor 80. In FIG. 14, an arrow with a sign D1 represents a distance between the first end 692a of the conductor layer 692 and the first conductor part 80E. An arrow with a sign D2 represents a distance between the second end 692b of the conductor layer 692 and the second conductor part 80F. The distance D1 is larger than the distance D2.

As shown in FIG. 14, the distance D1 is larger than each of the distance between the first end 691a of the conductor layer 691 of the first inductor L21 and the first conductor part 80E and the distance between the first end 693a of the conductor layer 693 of the third inductor L23 and the first conductor part 80E. The distance D2 is the same or approximately the same as each of the distance between the second end 691b of the conductor layer 691 of the first inductor L21 and the second conductor part 80F and the distance between the second end 693b of the conductor layer 693 of the third inductor L23 and the second conductor part 80F. Hence, the conductor layer 692 is shorter than each of the conductor layers 691 and 693.

Note that the shapes and arrangements of the conductor layers 701 to 703 are the same or approximately the same as the shapes and arrangements of the respective conductor layers 691 to 693 except for the positions in the stacking direction T. The description of the distances D1 and D2 above is also applicable to the conductor layers 701 to 703. The description of the distances D1 and D2 above with the conductor layers 691 to 693 being replaced by the respective conductor layers 701 to 703 can serve as description of the distances D1 and D2 related to the conductor layers 701 to 703.

The two columnar conductors T1a of the first inductor L21, the two columnar conductors T2a of the second inductor L22, and the two columnar conductors T3a of the third inductor L23 are at positions closer to the first conductor part 80E than to the second conductor part 80F. The two columnar conductors T1b of the first inductor L21, the two columnar conductors T2b of the second inductor L22, and the two columnar conductors T3b of the third inductor L23 are at positions closer to the second conductor part 80F than to the first conductor part 80E.

Next, features related to the shield conductor 80 and the ground will be described. The shield conductor 80 is connected to the electrodes 114, 115, and 116 connected to the ground via a plurality of conductors provided in the stack 50. Specifically, the second conductor part 80F and the conductor part 80C of the shield conductor 80 are connected to the conductor layers 584 and 664. The conductor layer 664 is connected to the conductor layer 584 via a plurality of through holes. The conductor layer 584 is connected to the conductor layer 532 via a plurality of through holes. The conductor layer 532 is connected to the conductor layer 521 via a plurality of through holes. The conductor layer 521 is connected to the electrode 114 via the two through holes 51T6 and also connected to the electrode 116 via the two through holes 51T8. The conductor layer 521 is connected to the conductor layer 534 via the two through holes 52T6 and the two through holes 52T8. The conductor layer 534 is connected to the electrode 115 via the two through holes 52T7, the conductor layer 524, and the two through holes 51T7.

The first conductor part 80E of the shield conductor 80 is connected to the conductor layers 581 and 681. The conductor layers 581 and 681 are connected to the two columnar conductors T1a of the first inductor L21 and the two columnar conductors T3a of the third inductor L23. The two columnar conductors T1a and the two columnar conductors T3a are connected to the electrodes 114, 115, and 116 via the conductor layer 534, the through holes 52T6, 52T7, and 52T8, the conductor layers 521 and 524, and the through holes 51T6, 51T7, and 51T8.

The second conductor part 80F of the shield conductor 80 is connected to the conductor layers 583 and 683. The conductor layers 583 and 683 are connected to the two columnar conductors T2b of the second inductor L22. The two columnar conductors T2b is connected to the electrodes 114, 115, and 116 via the conductor layer 534, the through holes 52T6, 52T7, and 52T8, the conductor layers 521 and 524, and the through holes 51T6, 51T7, and 51T8.

The two columnar conductors T1a of the first inductor L21 are electrically connected to the first conductor part 80E not via the conductor layer 691 and the two columnar conductors T1b of the first inductor L21. The two columnar conductors T2b of the second inductor L22 are electrically connected to the second conductor part 80F not via the conductor layer 692 and the two columnar conductors T2a of the second inductor L22. The two columnar conductors T3a of the third inductor L23 are electrically connected to the first conductor part 80E not via the conductor layer 693 and the two columnar conductors T3b of the third inductor L23.

Next, features related to the first to third inductors L21, L22, and L23, the shield conductor 80, and the ground will be described. As shown in FIG. 14 and FIG. 15, the electronic component 1 further includes a ground structure 30 provided in the stack 50 and connected to the ground. The ground structure 30 has such a shape as to surround the second inductor L22.

The ground structure 30 includes at least one columnar conductor extending in the stacking direction T and connected to the ground. In the example embodiment, the ground structure 30 includes two columnar conductors T5a and one columnar conductor T5b as at least one columnar conductor.

The two columnar conductors T5a are formed by connecting the through holes 53T5a, 54T5a, 55T5a, 56T5a, 57T5a, 58T5a, 59T5a, 62T5a, 63T5a, 64T5a, 65T5a, 66T5a, 67T5a, 68T5a, 69T5a, 70T5a, 71T5a, and 72T5a in series. The columnar conductor T5b is formed by connecting the through holes 53T5b, 54T5b, 55T5b, 56T5b, 57T5b, 58T5b, 59T5b, 62T5b, 63T5b, 64T5b, 65T5b, 66T5b, 67T5b, 68T5b, 69T5b, 70T5b, 71T5b, and 72T5b in series.

The ground structure 30 further includes ground conductor layers 534 and 731 arranged in the stack 50 and connected to the two columnar conductors T5a and one columnar conductor T5b. Each of the conductor layers 534 and 731 extends along a plane intersecting the stacking direction T.

The two columnar conductors T5a and one columnar conductor T5b are connected to the electrodes 114, 115, and 116 connected to the ground via the conductor layer 534, the through holes 52T6, 52T7, and 52T8, the conductor layers 521 and 524, and the through holes 51T6, 51T7, and 51T8. The two columnar conductors T5a are connected to the first conductor part 80E of the shield conductor 80 via the conductor layers 581 and 681.

The two columnar conductors T5a are arranged between the two columnar conductors T2a of the second inductor L22 and the first conductor part 80E of the shield conductor 80. Note that the two columnar conductors T5a are arranged so as not to overlap the first and third inductors L21 and L23 when seen in a direction perpendicular to the side surface 50E. The one columnar conductor T5b is arranged at a position closer to the side surface 50F than to the side surface 50E and closer to the two columnar conductors T2b of the second inductor L22 than to each of the side surfaces 50C and 50D.

The conductor layer 534 is arranged between the second inductor L22 and the second surface 50B. The conductor layer 731 is arranged between the second inductor L22 and the first surface 50A. Part of the conductor layer 731 overlaps at least part of the second inductor L22 when seen in the stacking direction T. In the example embodiment, as shown in FIG. 14, part of the conductor layer 731 overlaps at least part of the second inductor L22 when seen in the stacking direction T. The conductor layer 731 is interposed between the second inductor L22 and the conductor part 80A.

Note that, as shown in FIG. 14, part of the inductor conductor layer 692 of the second inductor L22 does not overlap the conductor layer 731 when seen in the stacking direction T. Similarly, part of the inductor conductor layer 702 of the second inductor L22 does not overlap the conductor layer 731 when seen in the stacking direction T.

Note that the conductor layer 731 is arranged so as not to overlap the first and third inductors L21 and L23 when seen in the stacking direction T.

The conductor layer 711 is connected to the second conductor part 80F of the shield conductor 80. The conductor layer 711 overlaps part of the second inductor L22 when seen in the stacking direction T. The conductor layer 711 is interposed between the second inductor L22 and the conductor part 80A. The conductor layer 711 is arranged so as not to overlap the conductor layer 731 when seen in the stacking direction T.

Next, features related to the fourth inductor L24 of the second filter 20 will be described. The fourth inductor L24 includes a conductor layer 651, a columnar conductor T4a connected to a portion of the conductor layer 651 near the first end, and a columnar conductor T4b connected to a portion of the conductor layer 651 near the second end. The columnar conductor T4a is formed by connecting the through holes 58T4a, 59T4a, 62T4a, 63T4a, and 64T4a in series. The columnar conductor T4b is formed by connecting the through holes 56T4b, 57T4b, 58T4b, 59T4b, 62T4b, 63T4b, and 64T4b in series.

The fourth inductor L24 further includes the conductor layer 582 and the through hole 57T4a connected to the conductor layer 582. The fourth inductor L24 is wound around a fourth axis orthogonal to the stacking direction T so as to form a fourth opening surrounded by the through hole 57T4a, the conductor layers 582 and 641, the columnar conductor T4a, and the columnar conductor T4b. The fourth axis may extend in a direction parallel to the Y direction.

The function and effects of the electronic component 1 according to the example embodiment will now be described. In the example embodiment, the two columnar conductors T5a connected to the ground are arranged between the second inductor L22 and the first conductor part 80E. With this, according to the example embodiment, coupling between the second inductor L22 and the first conductor part 80E can be weakened.

In the example embodiment, the ground conductor layer 731 connected to the two columnar conductors T5a is arranged between the second inductor L22 and the conductor part 80A. With this, according to the example embodiment, coupling between the second inductor L22 and the conductor part 80A can be weakened.

In the example embodiment, the electronic component 1 includes the first filter 10 and the second filter 20. The second filter 20 includes the second inductor L22. According to the example embodiment, coupling between the second inductor L22 and the shield conductor 80 can be weakened, which can suppress coupling between the first filter 10 and the second filter 20 via the second inductor L22 and the shield conductor 80 and can consequently suppress deterioration in isolation characteristics between the first filter 10 and the second filter 20.

In the example embodiment, the first filter 10 is provided between the common terminal 2 and the first signal terminal 3 in the circuit configuration, and the second filter 20 is provided between the common terminal 2 and the second signal terminal 4 in the circuit configuration. The first signal terminal 3, i.e., the electrode 112, is arranged at a position closer to the first conductor part 80E than to the second conductor part 80F. According to the example embodiment, by weakening the coupling between the second inductor L22 and the first conductor part 80E, coupling between the second inductor L22 and the electrode 112 via the first conductor part 80E can be suppressed, which can consequently suppress deterioration in isolation characteristics between the first signal terminal 3 and the second signal terminal 4.

Next, the effects of the example embodiment will be described with reference to results of a simulation. In the simulation, a model of an example and a model of a comparative example were used. The model of the example is a model of the electronic component 1 according to the example embodiment.

The model of the comparative example is a model of an electronic component of the comparative example. The electronic component of the comparative example is not provided with the ground structure 30. Specifically, in the comparative example, the conductor layer 731 of the ground structure 30 and the two columnar conductors T5a and the columnar conductor T5b are not provided. The configuration of the electronic component of the comparative example other than the above is the same as the configuration of the electronic component 1 according to the example embodiment.

In the simulation, frequency characteristics of isolation between the first signal terminal 3 and the second signal terminal 4 were obtained for each of the model of the example and the model of the comparative.

The definition of the isolation between the first signal terminal 3 and the second signal terminal 4 is as follows. When a high-frequency signal of a power P1 is input to the first signal terminal 3, the power of a signal output from the second signal terminal 4 is assumed as P2. Isolation I is defined by Equation (1) below.

$$I = - 10 log ( P 2 / P 1 ) \qquad ( 1 )$$

FIG. 16 is a characteristic chart showing the frequency characteristics of the isolation of each of the model of the example and the model of the comparative example. In FIG. 16, the horizontal axis represents frequency, and the vertical axis represents isolation. In FIG. 16, a curve denoted by a reference numeral 91 represents the frequency characteristics of the isolation in the model of the example. A curve denoted by a reference numeral 92 represents the frequency characteristics of the isolation in the model of the comparative example.

From FIG. 16, the isolation of the model of the example is larger than that of the model of the comparative example in a frequency region including the frequency range from 7737 MHz to 8237 MHz inclusive. As can be understood from this result, according to the example embodiment, it is possible to provide desired characteristics while suppressing occurrence of a problem attributable to the shield conductor 80.

Next, other effects of the example embodiment will be described. In the example embodiment, the distance D1 between the first end 682a of the conductor layer 682 of the second inductor L22 and the first conductor part 80E of the shield conductor 80 is larger than the distance D2 between the second end 682b of the conductor layer 682 and the second conductor part 80F of the shield conductor 80. With this, according to the example embodiment, it is possible to make the two columnar conductors T2a of the second inductor L22 away from the first conductor part 80E and also weaken the coupling between the two columnar conductors T2a and the first conductor part 80E.

In the example embodiment, the distance D1 is larger than each of the distance between the first end 691a of the conductor layer 691 of the first inductor L21 and the first conductor part 80E and the distance between the first end 693a of the conductor layer 693 of the third inductor L23 and the first conductor part 80E. With this, according to the example embodiment, it is possible to arrange the two columnar conductors T5a of the ground structure 30 between the first end 682a of the conductor layer 682 and the first conductor part 80E without increasing the stack 50 in size.

Note that the disclosure is not limited to the foregoing example embodiment, and various modifications can be made thereto. The disclosure is applicable, without being limited to the electronic component in the circuit configuration shown in FIG. 1, to electronic components of various circuit configuration as long as the requirements in the claims are satisfied.

The number of the plurality of columnar conductors of the second inductor L22 may be two or may be five or more. The number of the plurality of columnar conductors of the ground structure 30 may be two or may be three or more. Note that, however, the number of columnar conductors arranged between the second inductor L22 and the first conductor part 80E among the plurality of columnar conductors of the ground structure 30 is preferably equal to or larger than the number of columnar conductors connected near the first end 692a of the conductor layer 692 of the second inductor L22. Moreover, the number of columnar conductors arranged between the second inductor L22 and the first conductor part 80E among the plurality of columnar conductors of the ground structure 30 is preferably larger than the number of columnar conductors arranged near the second inductor L22 and the second conductor part 80F.

As described above, a multilayered electronic component according to a first aspect of one embodiment of the disclosure includes: a stack including a plurality of dielectric layers stacked together; a shield conductor integrated into the stack; at least one first columnar conductor and at least one second columnar conductor each extending in a stacking direction of the plurality of dielectric layers; an inductor including an inductor conductor layer connecting the at least one first columnar conductor and the at least one second columnar conductor; and at least one third columnar conductor extending in the stacking direction and connected to the ground. The stack has a first surface and a second surface located at both respective ends in the stacking direction and a first side surface, a second side surface, a third side surface, and a fourth side surface connecting the first surface and the second surface. The first side surface and the second side surface are opposite to each other. The third side surface and the fourth side surface are opposite to each other.

The shield conductor includes a first conductor part provided to the first side surface and a second conductor part provided to the second side surface. The inductor conductor layer has a first end and a second end extending from the first side surface toward the second side surface and located at both respective longitudinal-direction ends of the inductor conductor layer. The at least one first columnar conductor is connected to a portion of the inductor conductor layer near the first end. The at least one second columnar conductor is connected to a portion of the inductor conductor layer near the second end. The at least one third columnar conductor is arranged between the inductor and the first conductor part.

The multilayered electronic component according to the first aspect of the embodiment of the disclosure may further include a ground conductor layer arranged in the stack and connected to the at least one third columnar conductor. The ground conductor layer may be arranged between the inductor and the first surface. Part of the ground conductor layer may overlap at least part of the inductor when seen in one direction parallel to the stacking direction. The shield conductor may further include a third conductor part provided to the first surface. The multilayered electronic component according to the first aspect of the embodiment of the disclosure may further include another inductor including two columnar conductors each extending in the stacking direction and a conductor layer connecting the two columnar conductors. The ground conductor layer need not overlap the other inductor when seen in one direction parallel to the stacking direction.

The multilayered electronic component according to the first aspect of the embodiment of the disclosure may further include another inductor including two columnar conductors each extending in the stacking direction and a conductor layer connecting the two columnar conductors. The at least one third columnar conductor need not overlap the other inductor when seen in a direction perpendicular to the first side surface.

In the multilayered electronic component according to the first aspect of the embodiment of the disclosure, the at least one first columnar conductor may be arranged between the first side surface and the at least one second columnar conductor. The number of the at least one third columnar conductor may be equal to or larger than the number of the at least one first columnar conductor.

In the multilayered electronic component according to the first aspect of the embodiment of the disclosure, the first end of the inductor conductor layer may be at a position closer to the first conductor part than to the second conductor part. The second end of the inductor conductor layer may be at a position closer to the second conductor part than to the first conductor part. The distance between the first end of the inductor conductor layer and the first conductor part may be larger than the distance between the second end of the inductor conductor layer and the second conductor part.

In the multilayered electronic component according to the first aspect of the embodiment of the disclosure, the at least one first columnar conductor may be arranged at a position closer to the first side surface than to the second side surface. The at least one second columnar conductor may be arranged at a position closer to the second side surface than to the first side surface. The at least one second columnar conductor may be connected to the second conductor part.

The multilayered electronic component according to the first aspect of the embodiment of the disclosure may further include: a common terminal, a first signal terminal, and a second signal terminal provided to the second surface of the stack; a first circuit provided between the common terminal and the first signal terminal in a circuit configuration; and a second circuit provided between the common terminal and the second signal terminal in a circuit configuration. The second circuit may include an inductor. The first signal terminal may be arranged at a position closer to the first conductor part than to the second conductor part.

The multilayered electronic component according to the first aspect of the embodiment of the disclosure may further include at least one fourth columnar conductor extending in the stacking direction and connected to the ground. The at least one fourth columnar conductor may be arranged at a position closer to the second side surface than to the first side surface and closer to the inductor than to each of the third side surface and the fourth side surface. The number of the at least one third columnar conductor may be larger than the number of the at least one fourth columnar conductor.

A multilayered electronic component according to a second aspect of the embodiment of the disclosure includes: a stack including a plurality of dielectric layers stacked together; a shield conductor integrated into the stack; at least one first columnar conductor and at least one second columnar conductor each extending in a stacking direction of the plurality of dielectric layers; an inductor including an inductor conductor layer connecting the at least one first columnar conductor and the at least one second columnar conductor; and a ground conductor layer connected to the ground. The stack includes a first surface and a second surface located at both respective ends in the stacking direction. The shield conductor includes a conductor part provided to the first surface. The ground conductor layer is arranged between the inductor and the conductor part.

In the multilayered electronic component of the first aspect of the disclosure, the at least one third columnar conductor is arranged between the inductor and the first conductor part. In the multilayered electronic component of the second aspect of the disclosure, the ground conductor layer is arranged between the inductor and the conductor part. With these, according to the disclosure, it is possible to provide desired characteristics while suppressing occurrence of a problem attributable to the shield conductor.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A multilayered electronic component comprising:
a stack including a plurality of dielectric layers stacked together;
a shield conductor integrated into the stack;
an inductor including at least one first columnar conductor and at least one second columnar conductor each extending in a stacking direction of the plurality of dielectric layers and an inductor conductor layer connecting the at least one first columnar conductor and the at least one second columnar conductor; and
at least one third columnar conductor extending in the stacking direction and connected to ground, wherein
the stack includes a first surface and a second surface located at both respective ends in the stacking direction and a first side surface, a second side surface, a third side surface, and a fourth side surface connecting the first surface and the second surface,
the first side surface and the second side surface are opposite to each other,
the third side surface and the fourth side surface are opposite to each other,
the shield conductor includes a first conductor part provided to the first side surface and a second conductor part provided to the second side surface,
the inductor conductor layer includes a first end and a second end extending from the first side surface toward the second side surface and located at both respective longitudinal-direction ends of the inductor conductor layer,
the at least one first columnar conductor is connected to a portion of the inductor conductor layer near the first end,
the at least one second columnar conductor is connected to a portion of the inductor conductor layer near the second end, and
the at least one third columnar conductor is arranged between the inductor and the first conductor part.

2. The multilayered electronic component according to claim 1, further comprising a ground conductor layer arranged in the stack and connected to the at least one third columnar conductor.

3. The multilayered electronic component according to claim 2, wherein the ground conductor layer is arranged between the inductor and the first surface.

4. The multilayered electronic component according to claim 3, wherein part of the ground conductor layer overlap at least part of the inductor when seen in one direction parallel to the stacking direction.

5. The multilayered electronic component according to claim 3, wherein the shield conductor further includes a third conductor part provided to the first surface.

6. The multilayered electronic component according to claim 3, further comprising
another inductor including two columnar conductors each extending in the stacking direction and a conductor layer connecting the two columnar conductors, wherein
the ground conductor layer does not overlap the other inductor when seen in one direction parallel to the stacking direction.

7. The multilayered electronic component according to claim 1, further comprising
another inductor including two columnar conductors each extending in the stacking direction and a conductor layer connecting the two columnar conductors, wherein
the at least one third columnar conductor does not overlap the other inductor when seen in a direction perpendicular to the first side surface.

8. The multilayered electronic component according to claim 1, wherein
the at least one first columnar conductor is arranged between the first side surface and the at least one second columnar conductor, and
the number of the at least one third columnar conductor is equal to or larger than the number of the at least one first columnar conductor.

9. The multilayered electronic component according to claim 1, wherein
the first end of the inductor conductor layer is at a position closer to the first conductor part than to the second conductor part,
the second end of the inductor conductor layer is at a position closer to the second conductor part than to the first conductor part, and
a distance between the first end of the inductor conductor layer and the first conductor part is larger than a distance between the second end of the inductor conductor layer and the second conductor part.

10. The multilayered electronic component according to claim 1, wherein
the at least one first columnar conductor is arranged at a position closer to the first side surface than to the second side surface,
the at least one second columnar conductor is arranged at a position closer to the second side surface than to the first side surface, and
the at least one second columnar conductor is connected to the second conductor part.

11. The multilayered electronic component according to claim 1, further comprising:
a common terminal, a first signal terminal, and a second signal terminal provided to the second surface of the stack;
a first circuit provided between the common terminal and the first signal terminal in a circuit configuration; and
a second circuit provided between the common terminal and the second signal terminal in a circuit configuration, wherein
the second circuit includes the inductor, and
the first signal terminal is arranged at a position closer to the first conductor part than to the second conductor part.

12. The multilayered electronic component according to claim 1, further comprising
at least one fourth columnar conductor extending in the stacking direction and connected to the ground, wherein
the at least one fourth columnar conductor is arranged at a position closer to the second side surface than to the first side surface and closer to the inductor than to each of the third side surface and the fourth side surface.

13. The multilayered electronic component according to claim 12, wherein
the number of the at least one third columnar conductor is larger than the number of the at least one fourth columnar conductor.

14. A multilayered electronic component comprising:
a stack including a plurality of dielectric layers stacked together;
a shield conductor integrated into the stack;
an inductor including at least one first columnar conductor and at least one second columnar inductor each extending in a stacking direction of the plurality of dielectric layers and an inductor conductor layer connecting the at least one first columnar conductor and the at least one second columnar conductor; and
a ground conductor layer connected to ground, wherein
the stack includes a first surface and a second surface located at both respective ends in the stacking direction,
the shield conductor includes a conductor part provided to the first surface, and
the ground conductor layer is arranged between the inductor and the conductor part.
